(19) United States
(12) Patent Application Publication
(10) Pub. No.: US 2023/0420293 A1
(43) Pub. Date: Dec. 28, 2023

(54) METHOD OF MANUFACTURING SEMICONDUCTOR STRUCTURE AND SEMICONDUCTOR STRUCTURE

(71) Applicant: CHANGXIN MEMORY TECHNOLOGIES, INC., Hefei City (CN)

(72) Inventors: Zhaopei CUI, Hefei City (CN); Ying SONG, Hefei City (CN)

(21) Appl. No.: 17/935,161

(22) Filed: Sep. 26, 2022

Related U.S. Application Data
(63) Continuation of application No. PCT/CN2022/106524, filed on Jul. 9, 2022.

(30) Foreign Application Priority Data
Jun. 24, 2022 (CN) 202210722837.1

(51) Int. Cl. H01L 21/768; H01L 21/8234; H01L 21/3213

(52) U.S. Cl. CPC H01L 21/76832; H01L 21/823437; H01L 21/76849; H01L 21/76811; H01L 21/3213

(57) ABSTRACT

A method of manufacturing a semiconductor structure and a semiconductor structure are disclosed. The method of manufacturing a semiconductor structure includes: providing a substrate; forming a multilayer film stack on the substrate; forming a supporter at a top of the multilayer film stack; and etching the multilayer film stack to form a plurality of gate structures arranged at intervals along a first direction, where the supporter penetrates a top of each of the plurality of gate structures and extends along the first direction.

### CROSS-REFERENCE TO RELATED APPLICATIONS

The present disclosure is a continuation application of International Patent Application No. PCT/CN2022/106524, filed on Jul. 19, 2022, which claims the priority to Chinese Patent Application No. 202210722837.1, titled “METHOD OF MANUFACTURING SEMICONDUCTOR STRUCTURE AND SEMICONDUCTOR STRUCTURE” and filed on Jun. 24, 2022. The entire contents of International Patent Application No. PCT/CN2022/106524 and Chinese Patent Application No. 202210722837.1 are incorporated herein by reference.

### TECHNICAL FIELD

The present disclosure relates to, but is not limited to, a method of manufacturing a semiconductor structure and a semiconductor structure.

### BACKGROUND

With the advancement of technology, dynamic random access memory (DRAM) is developing in the direction of high speed, high integration density and low power consumption. The structure size of the DRAM device is getting smaller. Especially, in the process of manufacturing semiconductor devices with a low line width, the material, shape, size and electrical properties of a gate structure need to meet higher requirements.

The current manufacturing process usually requires multiple wet cleaning processes to obtain the required gate structure, and the gate structure is prone to peeling during the cleaning process, which affects the electrical properties of the gate structure.

### SUMMARY

A first aspect of the present disclosure provides a method of manufacturing a semiconductor structure. The method of manufacturing a semiconductor structure includes:
providing a substrate;
forming a multilayer film stack on the substrate;
forming a supporter at a top of the multilayer film stack; and
etching the multilayer film stack to form a plurality of gate structures arranged at intervals along a first direction, the supporter penetrating a top of each of the plurality of gate structures and extending along the first direction.

A second aspect of the present disclosure provides a semiconductor structure, where the semiconductor structure includes:
a substrate;
a plurality of gate structures, located on the substrate and arranged at intervals along a first direction; and
a supporter, penetrating a top of each of the plurality of gate structures and extending along the first direction.

### BRIEF DESCRIPTION OF THE DRAWINGS

The accompanying drawings incorporated into the specification and constituting a part of the specification illustrate the embodiments of the present disclosure, and are used together with the description to explain the principles of the embodiments of the present disclosure. In these accompanying drawings, similar reference numerals are used to represent similar elements. The accompanying drawings in the following description are some rather than all of the embodiments of the present disclosure. Those skilled in the art may obtain other accompanying drawings based on these accompanying drawings without creative efforts.

FIG. 1 is a schematic diagram of a semiconductor structure in the related art.

FIG. 2 is a flowchart of a method of manufacturing a semiconductor structure according to an exemplary embodiment.

FIG. 3 is a schematic diagram of the semiconductor structure after a multilayer film stack is formed according to an exemplary embodiment.

FIG. 4 is a schematic diagram of the semiconductor structure after a support material layer is formed according to an exemplary embodiment.

FIG. 5 is a schematic diagram of the semiconductor structure after a first mask layer and a first photoresist layer are formed according to an exemplary embodiment.

FIG. 6 is a schematic diagram of the semiconductor structure after a supporter is formed according to an exemplary embodiment.

FIG. 7 is a schematic diagram of the semiconductor structure after a supplementary material layer is formed according to an exemplary embodiment.

FIG. 8 is a schematic diagram of the semiconductor structure after a third mask layer and a third photoresist layer are formed according to an exemplary embodiment.

FIG. 9 is a schematic diagram of the semiconductor structure after a plurality of gate structures are formed according to an exemplary embodiment.

FIG. 10 is a cross-sectional view taken along A-A in FIG. 9.

FIG. 11 is a schematic diagram of the semiconductor structure after a second mask layer and a second photoresist layer are formed according to an exemplary embodiment.

FIG. 12 is a schematic diagram of the semiconductor structure after a first trench is formed according to an exemplary embodiment.

FIG. 13 is a schematic diagram of the semiconductor structure after a supporter is formed according to an exemplary embodiment.

### DETAILED DESCRIPTION

To make the objectives, technical solutions, and advantages of the embodiments of the present disclosure clearer, the following clearly and completely describes the technical solutions in the embodiments of the present disclosure with reference to the accompanying drawings in the embodiments of the present disclosure. Apparently, the described embodiments are some but not all of the embodiments of the present disclosure. All other embodiments obtained by those skilled in the art based on the embodiments of the present disclosure without creative efforts should fall within the protection scope of the present disclosure. It should be noted that the embodiments in the present disclosure and features in the embodiments may be combined with each other in a non-conflicting manner.

As the dynamic random access memory (DRAM) develops in the direction of high speed, high integration density and low power consumption, the structure size of the DRAM device is getting smaller. Especially, in the process of manufacturing semiconductor devices with a low line width, the material, shape, size and electrical properties of a gate structure need to meet higher requirements.

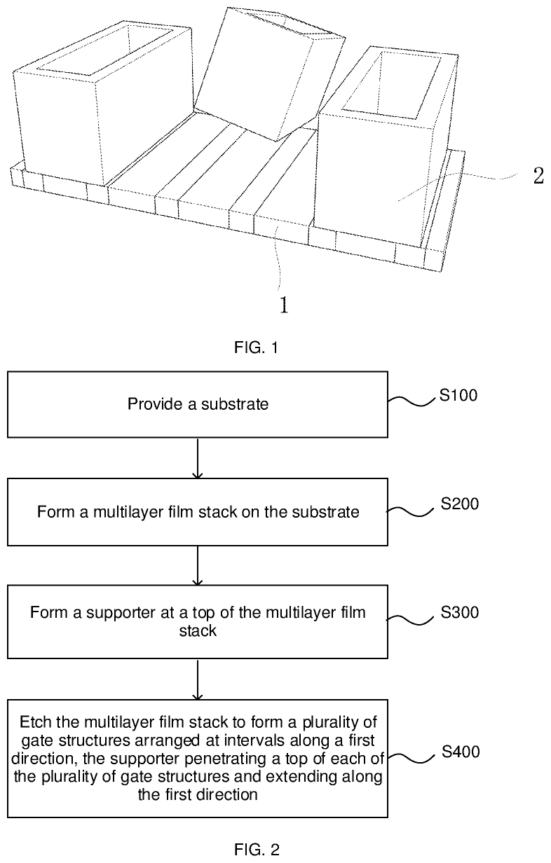

FIG. 1 shows a semiconductor structure in the related art. The semiconductor structure includes a substrate 1 and a plurality of gate structures 2 arranged on the substrate 1. The current manufacturing process usually requires multiple wet cleaning processes to obtain the required gate structure 2. During the cleaning process, due to the small critical dimension of the gate structure 2 and the large height of the gate structure 2 (vertically upward perpendicular to the substrate), the gate structure 2 is peeled off from the substrate 1 after repeated cleaning, which affects the electrical performance of the gate structure 2.

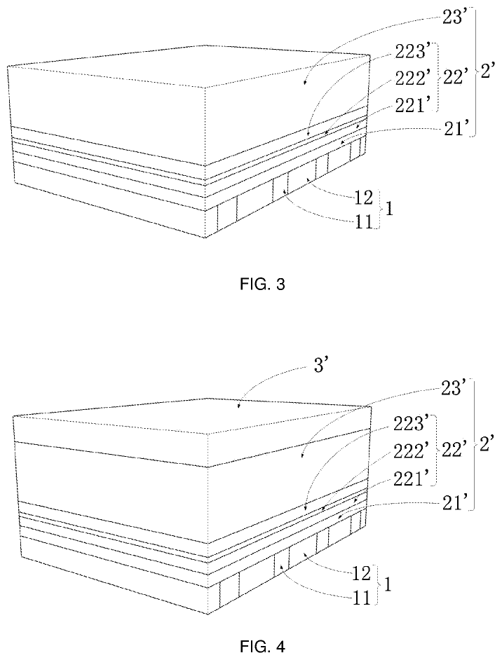

An exemplary embodiment of the present disclosure provides a method of manufacturing a semiconductor structure. FIG. 2 is a flowchart of a method of manufacturing a semiconductor structure according to an exemplary embodiment of the present disclosure. FIG. 3 to FIG. 13 are schematic diagrams of the method of manufacturing a semiconductor structure at various stages. The method of manufacturing a semiconductor structure is described below with reference to FIG. 3 to FIG. 13.

The semiconductor structure is not limited in this embodiment. The semiconductor structure is described below by using a DRAM as an example, but this embodiment is not limited thereto. Alternatively, the semiconductor structure in this embodiment may further be another structure.

As shown in FIG. 2, an exemplary embodiment of the present disclosure provides a method of manufacturing a semiconductor structure. The method includes the following steps:

Step S100: Provide a substrate.

As shown in FIG. 3, a material of the substrate 1 may be silica (Si), germanium (Ge), silicon-germanium (GeSi), or silicon carbide (SiC); or may be silicon on insulator (SOI) or germanium on insulator (GOI); or may further be another material, for example, a III-V compound such as gallium arsenide. The substrate 1 is configured to support elements provided thereon.

The substrate 1 may be doped with certain impurity ions as required, and the impurity ions may be N-type impurity ions or P-type impurity ions. In some embodiments, the doping includes well region doping and source drain region doping. In this embodiment, a plurality of transistors may be formed in the substrate 1. If the plurality of transistors are used as a part of the DRAM memory, specifically, as shown in FIG. 3, a plurality of active areas 11 arranged at intervals are provided in the substrate 1, and adjacent active areas 11 are isolated from each other by a shallow trench isolation region 12. The active area 11 includes a channel region, and a source region and a drain region that are located on two sides of the channel region. The source region and the drain region are formed by a source drain doping process.

Step S200: Form a multilayer film stack on the substrate.

In this example, as shown in FIG. 3, a multilayer film stack 2′ may be formed on the substrate 1 through a deposition process, such as atomic layer deposition (ALD) or chemical vapor deposition (CVD). In this embodiment, the multilayer film stack 2′ may be configured to form the gate structures 2 in post-processing.

In some embodiments, before the multilayer film stack 2′ is formed, wet cleaning is performed on the substrate 1, thereby removing impurities on the surface of the substrate 1, to provide good interface performance and process foundation for subsequent processes, thus helping improve the quality of the semiconductor structure.

Step S300: Form a supporter at a top of the multilayer film stack.

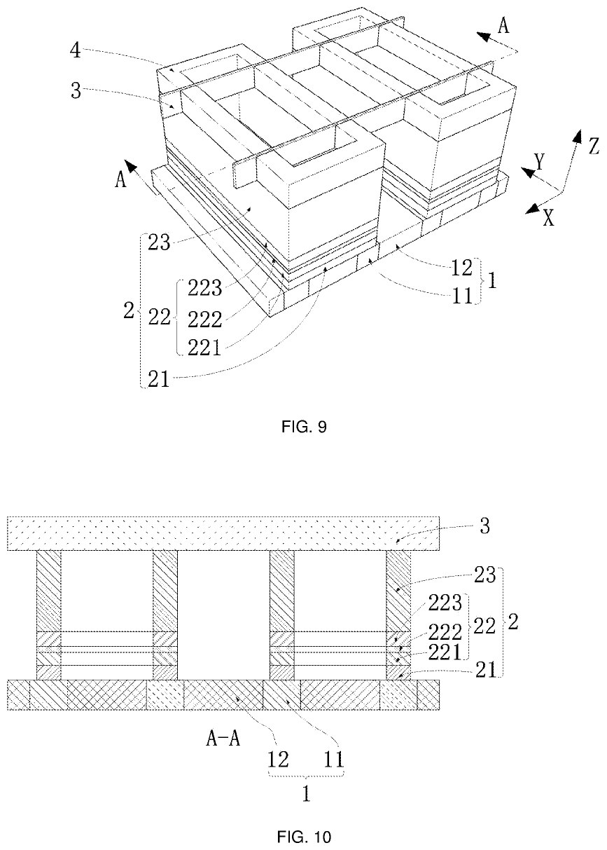

In this step, referring to FIG. 9, the supporter 3 may be formed on the multilayer film stack 2′ through a deposition process. The deposition process has been explained, and details are not described herein again. This embodiment shows a semiconductor structure provided with two supporters 3. It is to be understood that, only one supporter 3 may be provided, and the one supporter 3 extends along the first direction (direction X shown in FIG. 9). More supporters 3 may be provided, where the plurality of supporters 3 are arranged along a second direction (direction Y shown in FIG. 9), and each supporter 3 extends along the first direction.

In an example, referring to FIG. 4 to FIG. 6, the support material layer 3′ may be formed on the multilayer film stack 2′ first. Then, a part of the support material layer 3′ is removed through lithography, etching, or other processes, and the retained part of the support material layer 3′ forms the supporter 3.

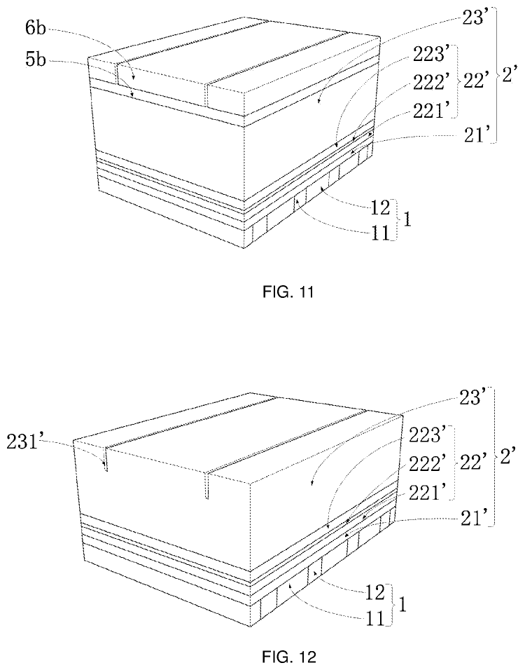

In an example, referring to FIG. 11 to FIG. 13, a part of the multilayer film stack 2′ may be removed through lithography, etching, or other processes first, and then the supporter 3 is formed through a deposition process in the region in which the multilayer film stack 2′ is removed.

Step S400: Etch the multilayer film stack to form a plurality of gate structures arranged at intervals along a first direction, the supporter penetrating a top of each of the plurality of gate structures and extending along the first direction.

In this step, as shown in FIG. 8 and FIG. 9, the multilayer film stack 2′ may be etched through an etching process, to form a plurality of gate structures 2 arranged at intervals along the first direction (direction X in FIG. 9), where the supporter 3 penetrates the top of each of the plurality of gate structures 2 and extends along the first direction.

Referring to FIG. 8 and FIG. 9, this embodiment shows an example in which a plurality of gate structures 2 are formed and every two gate structures 2 form an annular gate group. That is, a mask layer (not shown in the figure) with a block pattern is formed, and the multilayer film stack 2′ covered by the block pattern of the mask layer is protected in the etching process and is thus retained; the multilayer film stack 2′ not covered by the block pattern of the mask layer is removed by etching, to finally form an annular gate group. The formation of the annular gate group does not constitute limitation on the present disclosure. It may be understood that, the shape of the gate structure 2 is related to the preset pattern on the mask layer. When the preset pattern on the mask layer is a plurality of strips arranged at intervals, the formed gate structure 2 is strip-shaped.

In an example, as shown in FIG. 9, a material of the supporter 3 and a material of the multilayer film stack 2′ have different etch selectivities, such that in the same etching environment, only a part of the multilayer film stack 2′ is removed while the supporter 3 is retained, to form the supporter 3 penetrating the plurality of gate structures 2.

In this embodiment, a supporter 3 is first formed on a multilayer film stack 2′, and then the multilayer film stack 2′ is etched to form a plurality of gate structures 2 arranged at intervals along a first direction, where the supporter 3 extends along the first direction and penetrates a top of each of the plurality of gate structures 2. A depth-to-width ratio of the gate structure 2 can be effectively improved by setting the supporter 3, thereby improving the electrical performance of the semiconductor structure. The supporter 3 reliably supports and connects the plurality of gate structures 2, thereby effectively avoiding peeling of the gate structure 2 during processes such as cleaning, to ensure the product yield.

In an exemplary embodiment, step S200 may specifically include the following steps:

Step S210: Form a gate dielectric material layer to cover a top surface of the substrate.

In this step, as shown in FIG. 3, the gate dielectric material layer 21′ may be formed on the top surface of the substrate 1 through a deposition process. The deposition process has been explained in the foregoing embodiment, and details are not described herein again. In this step, a material of the gate dielectric material layer 21′ may be silicon dioxide (SiO2). In other embodiments, the material of the gate dielectric material layer 21′ may be at least one of silicon oxynitride (SiON) and silicon nitride (SiN). One or more gate dielectric material layers 21′ may be provided. When a plurality of gate dielectric material layers 21′ are provided, the gate dielectric material layers 21′ may be made of a same material or different materials.

Step S220: Form a gate conductive material layer to cover a top surface of the gate dielectric material layer.

In this step, as shown in FIG. 3, the gate conductive material layer 22′ may be formed through a deposition process. The gate conductive material layer 22′ may be a multilayer film stack including a semiconductor conductive layer and a metal layer. A material of the semiconductor conductive layer may be polysilicon. A material of the metal layer may be tungsten (W). In other embodiments, the gate conductive material layer 22′ may also be a single-layer structure only including a metal layer. The material of the metal layer may further be at least one of copper (Cu), gold (Au), and silver (Ag).

Step S220 may specifically include the following steps:

Step S221: Form a first conductive material layer to cover the top surface of the gate dielectric material layer.

In this step, referring to FIG. 3, the first conductive material layer 221′ is the semiconductor material layer in the foregoing embodiment, and details are not described herein again.

Step S222: Form a barrier material layer to cover a top surface of the first conductive material layer 221′.

In this step, the barrier material layer 222′ is configured to prevent inter-diffusion between the metal layer and the semiconductor conductive layer. The barrier material layer 222′ may be formed through a deposition process. A material of the barrier material layer 222′ may be titanium nitride (TiN).

Step S223: Form a second conductive material layer to cover the barrier material layer.

In this step, referring to FIG. 3, the second conductive material layer 223′ is the metal layer in the foregoing embodiment, and details are not described herein again.

Step S230: Form an insulation material cap layer to cover a top surface of the gate conductive material layer.

In this step, as shown in FIG. 3, the insulation material cap layer 23′ may be formed through a deposition process. In this embodiment, a material of the insulation material cap layer 23′ is silicon nitride (SiN). In other embodiments, the insulation material cap layer 23′ may also be made of silicon oxynitride (SiON) or other insulation materials. One or more insulation material cap layers 23′ may be provided. When a plurality of insulation material cap layers 23′ are provided, the insulation material cap layers 23′ may be made of a same material or different materials.

Referring to FIG. 2, the gate dielectric material layer 21′, the gate conductive material layer 22′ and the insulation material cap layer 23′ jointly constitute the multilayer film stack 2′.

In an embodiment, after the multilayer film stack 2′ is formed, step S310 may be performed, to form the supporter 3 at the top of the multilayer film stack 2′.

Referring to FIG. 4 to FIG. 6, step S310 includes the following steps:

Step S311: Form a support material layer on the insulation material cap layer.

In this step, as shown in FIG. 4, the support material layer 3′ may be formed on the insulation material layer through a deposition process. It needs to be ensured that the support material layer 3′ and the multilayer film stack 2′ have a specific etch selectivity. The etch selectivity between the support material layer 3′ and the multilayer film stack 2′ is less than 1:10. For example, when the material of the multilayer film stack 2′ is the material in the foregoing embodiment, the material of the support material layer 3′ may be silicon carbonitride (SiCN).

Step S312: Form a first mask layer on the support material layer.

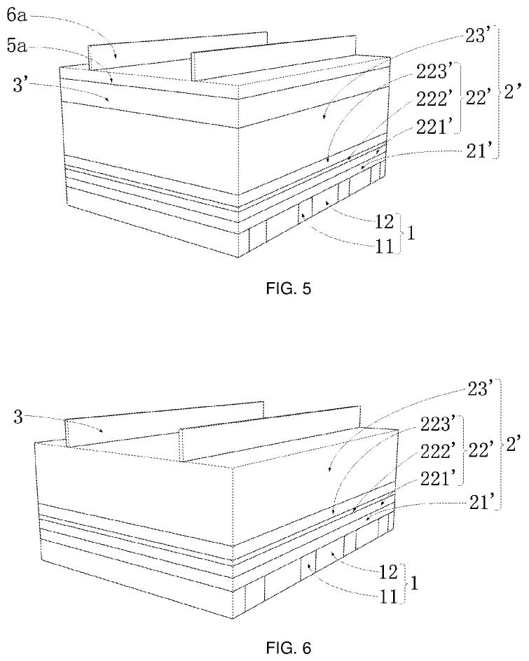

In this step, as shown in FIG. 5, the first mask layer 5a may be formed on the support material layer 3′ through a deposition process. A material of the first mask layer 5a may be silicon oxide (SiO₂), silicon nitride (SiN), silicon oxynitride (SiON), or titanium nitride (TiN).

Step S313: Form a patterned first photoresist layer on the first mask layer, where the patterned first photoresist layer includes a first preset pattern extending along the first direction.

In this step, as shown in FIG. 5, the patterned first photoresist layer 6a may be formed on the first mask layer 5a through a deposition process. The patterned first photoresist layer 6a includes a first preset pattern extending along the first direction, and the first preset pattern may be strip-shaped, to form a strip-shaped supporter 3 in post-processing. A material of the first photoresist layer 6a may be silicon oxide (SiO₂), silicon nitride (SiN), silicon oxynitride (SiON), or titanium nitride (TiN).

Step S314: Pattern the first mask layer based on the first photoresist layer, to transfer the first preset pattern to the first mask layer.

In this step, as shown in FIG. 5, downward (the direction opposite to direction Z shown in FIG. 9) etching may be performed by using an etching process. The first mask layer 5a covered by the first photoresist layer 6a will not be removed by etching, and the exposed surface of the first mask layer 5a is removed by etching.

Step S315: Etch the support material layer by using the patterned first mask layer as a mask, to obtain the supporter.

In this step, as shown in FIG. 6, the first preset pattern on the first mask layer 5a may be transferred to the support material layer 3′ through an etching process, to remove a partial structure of the support material layer 3′, and the retained part of the support material layer 3′ forms the supporter 3. In another embodiment (this embodiment is not shown in the drawings), a photoresist layer having a first preset pattern may be formed on the support material layer 3′. The first preset pattern in the photoresist layer may be transferred to the support material layer 3′ through dry etching, to remove a partial structure of the support material layer 3′.

After a partial structure of the support material layer 3′ is removed through an etching process, the mask is removed through an ashing process, and impurities in the removed region of the support material layer 3′ are removed through wet etching, to provide good interface performance and process foundation for subsequent processes, thus helping improve the quality of the formed semiconductor.

In an embodiment, after the multilayer film stack 2′ is formed, step S320 may also be performed, to form the supporter 3 at the top of the multilayer film stack 2′.

Referring to FIG. 11 to FIG. 13, step S320 includes the following steps:

Step S321: Form a second mask layer on the multilayer film stack.

In this step, referring to FIG. 11, the second mask layer 5b may be formed on the multilayer film stack 2′ through a deposition process. The implementation manner and optional materials of the second mask layer 5b are the same as those of the first mask layer 5a in step S312, and details are not described herein again.

Step S322: Form a patterned second photoresist layer on the second mask layer, where the patterned second photoresist layer includes a second preset pattern extending along the first direction.

In this step, referring to FIG. 11, the patterned second photoresist layer 6b may be formed on the second mask layer 5b through a deposition process, where the patterned second photoresist layer 6b includes the second preset pattern extending along the first direction. The implementation manner and optional materials of the second photoresist layer 6b are the same as those of the first photoresist layer 6a, and details are not described herein again.

Step S323: Pattern the second mask layer based on the second photoresist layer, to transfer the second preset pattern to the second mask layer.

In this step, as shown in FIG. 11, the second mask layer 5b not covered by the second photoresist layer 6b may be etched through an etching process, to transfer the second preset pattern on the second photoresist layer 6b to the second mask layer 5b.

Step S324: Etch the insulation material cap layer by using the patterned second mask layer as a mask to obtain a first trench.

In this step, as shown in FIG. 12, the second preset pattern on the second mask layer 5b may be transferred to the insulation material cap layer 23′ through an etching process, thereby removing a partial structure of the insulation material cap layer 23′, and the first trench 231′ is formed in the removed region of the insulation material cap layer 23′. In another embodiment (this embodiment is not shown in the drawings), a photoresist layer having a second preset pattern may be formed on the insulation material cap layer 23′. The second preset pattern in the photoresist layer may be transferred to the insulation material cap layer 23′ through dry etching, to remove a partial structure on the insulation material cap layer 23′, thereby forming the first trench 231′.

Step S325: Fill the first trench with a support material layer to form the supporter.

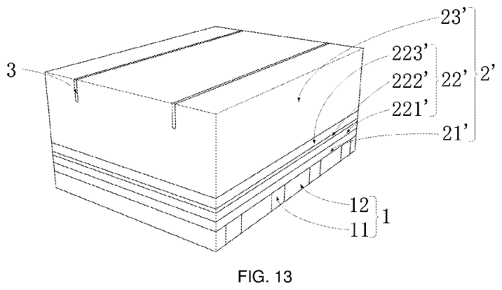

In this step, as shown in FIG. 13, a support material deposited and filled in the first trench 231′ through a deposition process. The support material filling the first trench 231′ forms the supporter 3.

In an example, the support material may be deposited on the upper surface of the insulation material cap layer 23′. After the deposition, the support material may be removed through chemical mechanical polishing (CMP), to expose the covered surface of the insulation material cap layer 23′, ensuring that the support material only exists in the first trench 231′, and the support material in the first trench 231′ forms the supporter 3.

In an example, a mask having a preset pattern may be disposed on the insulation material cap layer 23′, where the mask exposes the first trench 231′, thereby depositing the support material in the first trench 231′.

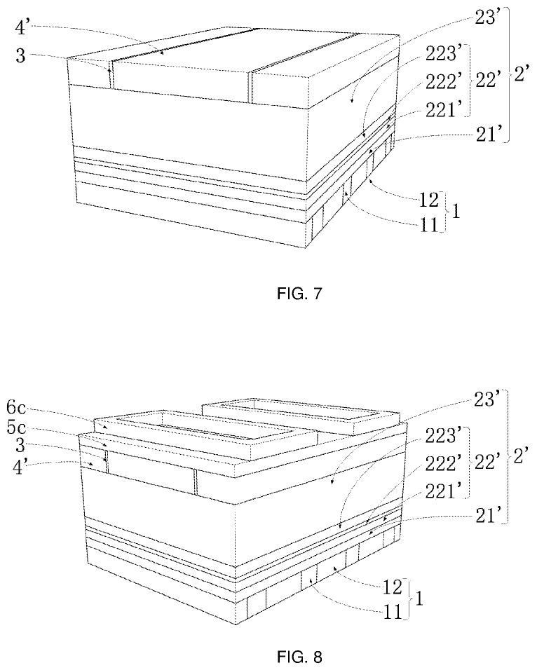

In an exemplary embodiment, as shown in FIG. 7 to FIG. 9, step S400 in the foregoing embodiment specifically includes the following steps:

Step S410: Form a third mask layer on the supporter and the multilayer film stack.

In this step, as shown in FIG. 8, the third mask layer 5c may be formed on the supporter 3 and the multilayer film stack 2′ through a deposition process. The implementation manner of the third mask layer 5c is the same as that of the first mask layer 5a and the second mask layer 5b in the foregoing embodiment, and details are not described herein again.

Step S420: Form a patterned third photoresist layer on the third mask layer, where the patterned third photoresist layer includes third preset patterns arranged at intervals along the first direction.

In this step, as shown in FIG. 8, the patterned third photoresist layer 6c may be formed on the third mask layer 5c through a deposition process, where the patterned third photoresist layer 6c includes the third preset patterns arranged at intervals along the first direction. The implementation manner of the third photoresist layer 6c is the same as those of the first photoresist layer 6a and the second photoresist layer 6b, and details are not described herein again.

FIG. 8 shows a third photoresist layer 6c having block-shaped third preset patterns, to form block-shaped gate structures 2 in subsequent processes. In other embodiments, third preset patterns in other shapes such as strip shapes may be formed, thereby forming strip-shaped gate structures 2.

Step S430: Pattern the third mask layer based on the third photoresist layer, to transfer the third preset patterns to the third mask layer.

In this step, as shown in FIG. 8, the third mask layer 5c not covered by the third photoresist layer 6c may be etched by using an etching process, to transfer the third preset patterns on the third photoresist layer 6c to the third mask layer 5c.

Step S440: Etch the multilayer film stack by using the patterned third mask layer as a mask, to obtain the plurality of gate structures arranged at intervals along the first direction, and retain the supporter at the top of each of the gate structures.

In this step, as shown in FIG. 9, the third preset patterns on the third mask layer 5c may be transferred to the multilayer film stack 2′ through an etching process, thereby removing a partial structure in the multilayer film stack 2′, such that the retained multilayer film stack 2′ forms the gate structures 2.

An etch selectivity between the supporter 3 and the multilayer film stack 2′ is less than 1:10, such that in the etching process, the multilayer film stack 2′ not covered by the third mask layer 5c is removed by etching, and the supporter 3 has an inert reaction with an etching gas, thereby being retained.

In the etching process, during downward (an opposite direction of direction X shown in FIG. 9) etching of the etching gas, the etching gas diffuses to a certain extent in the horizontal direction (a plane in which direction X and direction Y are located in FIG. 9). By setting a width of the supporter 3 in the second direction (direction Y shown in FIG. 9) to 2 nm to 10 nm, the etching gas can only remove the multilayer film stack 2′ right below the supporter 3.

In first exemplary embodiments, in the method of manufacturing a semiconductor structure provided by the embodiments of the present disclosure, after the supporter 3 is formed and before the multilayer film stack 2′ is etched, the method further includes the following steps:

Step S330: Form a supplementary material layer on the multilayer film stack.

In this step, as shown in FIG. 6 and FIG. 7, the supplementary material layer 4′ may be formed through a deposition process. A material of the supplementary material layer 4′ may be any one or more from the group consisting of hafnium oxide (HfO2), aluminum oxide (Al2O3), and silicon dioxide (SiO2). The supplementary material layer 4′ is formed, such that the supplementary material layer 4′ wraps side surfaces of the supporter 3, thereby improving the connection strength between the supporter 3 and the gate structure 2.

After the supplementary material is formed, the method may further include the following step:

Step S331: Planarize the supplementary material layer.

In this step, as shown in FIG. 7, the supplementary material layer 4′ is planarized to ensure the flatness of the upper-layer structure. The supplementary material layer 4′ is planarized through chemical mechanical polishing (CMP).

An embodiment of the present disclosure further provides a semiconductor structure. As shown in FIG. 9 and FIG. 10, the semiconductor structure includes a substrate 1, a plurality of gate structures 2, and a supporter 3. A material of the substrate 1 may be silicon (Si), germanium (Ge), silicon-germanium (GeSi), or silicon carbide (SiC); or may be silicon on insulator (SOI) or germanium on insulator (GOI); or may further be another material, for example, a III-V compound such as gallium arsenide. The substrate 1 is configured to support elements provided thereon. The substrate 1 may be doped with certain impurity ions as required, and the impurity ions may be N-type impurity ions or P-type impurity ions. In some embodiments, the doping includes well region doping and source drain region doping. In this embodiment, a plurality of transistors may be formed in the substrate 1. If the plurality of transistors are used as a part of the DRAM memory, a plurality of active areas 11 arranged at intervals are provided in the substrate 1, and adjacent active areas 11 are isolated from each other by a shallow trench isolation region 12. The active area 11 includes a channel region, and a source region and a drain region that are located on two sides of the channel region. The source region and the drain region are formed through source drain doping.

As shown in FIG. 9 and FIG. 10, the plurality of gate structures 2 are located on the substrate 1, and are arranged at intervals along a first direction. One shallow trench isolation region 12 is provided between two adjacent gate structures 2. FIG. 9 shows a semiconductor structure with four gate structures 2. Every two gate structures form a gate group, and the two gate structures forming the gate group forms a ring, so as to form an annular gate. It may be understood that, more gate structures 2 may be arranged in the first direction, and thus the plurality of gate structures 2 may form 3, 4, 5, or 6 gate groups.

As shown in FIG. 9 and FIG. 10, the gate structure 2 includes a gate dielectric layer 21, a gate conductive layer 22, and an insulation cap layer 23. Referring to FIG. 9 and FIG. 10, the gate dielectric layer 21 is located on the substrate 1 and covers the top surface of the substrate 1. A material of the gate dielectric layer 21 may be at least one from the group consisting of silicon oxide (SiO2), silicon oxynitride (SiON), and silicon nitride (SiN). Referring to FIG. 9 to FIG. 10, the gate conductive layer 22 is located on the gate dielectric layer 21 and covers the top surface of the gate dielectric layer 21. The gate conductive layer 22 specifically includes a first conductive layer 221, a barrier layer 222, and a second conductive layer 223. The first conductive layer 221 is located on the gate dielectric layer 21, the barrier layer 222 is located on the first conductive layer 221, and the second conductive layer 223 is located on the barrier layer 222. A material of the first conductive layer 221 may be polysilicon; a material of the barrier layer 222 may be titanium nitride (TiN); a material of the second conductive layer 223 may be at least one from the group consisting of tungsten (W), copper (Cu), gold (Au), and silver (Ag).

As shown in FIG. 9 and FIG. 10, the supporter 3 penetrates a top of each of the plurality of gate structures 2, and extends along the first direction (direction X shown in FIG. 9). The supporter 3 penetrates a top of the insulation cap layer 23 of the gate structure 2. A material of the gate structure 2 may be silicon carbonitride (SiCN). The gate structure 2 has a width of 2 nm to 10 nm in a second direction (direction Y shown in FIG. 9). By setting the width of the gate structure 2 within the above range, sufficient support strength can be implemented, and in the process of etching the multilayer film stack 2′, the multilayer film stack 2′ below the supporter 3 can be removed by etching. It may be understood that, in the process of etching the multilayer film stack 2′ downward (the direction opposite to direction Z shown in FIG. 9), an etching gas diffuses in a certain range in the horizontal direction (a plane in which direction X and direction Y are located in FIG. 9), thereby removing the multilayer film stack 2′ below the supporter 3.

It should be noted that, a material of the multilayer film stack 2′ is different from that of the supporter 3. An etch selectivity between the supporter 3 and the multilayer film stack 2′ is less than 1:10, such that only the multilayer film stack 2′ is removed by etching in the process of etching the multilayer film stack 2′, while the supporter 3 can be retained.

In this embodiment, the supporter 3 is provided on the plurality of gate structures 2, and the supporter 3 penetrates the top of each of the plurality of gate structures 2. An extension direction of the supporter 3 is the same as the arrangement direction of the gate structures 2, which improves the depth-to-width ratio of the gate structure 2, thereby improving the electrical performance of the semiconductor device. Moreover, the supporter 3 avoids peeling of the gate structure 2 in the subsequent multiple cleaning processes.

In an exemplary embodiment, as shown in FIG. 9, the semiconductor structure further includes a supplementary layer 4. The supplementary layer 4 is located on the insulation cap layer 23, and the supporter 3 penetrates the supplementary layer 4. In an example, referring to step S310 in the foregoing embodiment, the supplementary layer 4 is formed after formation of the supporter 3. Optional materials of the supplementary layer 4 are the same as those of the insulation cap layer 23, and details are not described herein again.

The embodiments or implementations of this specification are described in a progressive manner, and each embodiment focuses on differences from other embodiments. The same or similar parts between the embodiments may refer to each other.

In the description of this specification, the description with reference to terms such as “an embodiment”, “an exemplary embodiment”, “some implementations”, “a schematic implementation”, and “an example” means that the specific feature, structure, material, or characteristic described in combination with the implementation(s) or example(s) is included in at least one implementation or example of the present disclosure.

In this specification, the schematic expression of the above terms does not necessarily refer to the same implementation or example. Moreover, the described specific feature, structure, material or characteristic may be combined in an appropriate manner in any one or more implementations or examples.

It should be noted that in the description of the present disclosure, the terms such as “center”, “top”, “bottom”, “left”, “right”, “vertical”, “horizontal”, “inner” and “outer” indicate the orientation or position relationships based on the accompanying drawings. These terms are merely intended to facilitate description of the present disclosure and simplify the description, rather than to indicate or imply that the mentioned apparatus or element must have a specific orientation and must be constructed and operated in a specific orientation. Therefore, these terms should not be construed as a limitation to the present disclosure.

It can be understood that the terms such as “first” and “second” used in the present disclosure can be used to describe various structures, but these structures are not limited by these terms. Instead, these terms are merely intended to distinguish one structure from another.

The same elements in one or more accompanying drawings are denoted by similar reference numerals. For the sake of clarity, various parts in the accompanying drawings are not drawn to scale. In addition, some well-known parts may not be shown. For the sake of brevity, a structure obtained by implementing a plurality of steps may be shown in one figure. In order to understand the present disclosure more clearly, many specific details of the present disclosure, such as the structure, material, size, processing process, and technology of the device, are described below. However, as those skilled in the art can understand, the present disclosure may not be implemented according to these specific details.

Finally, it should be noted that the above embodiments are merely intended to explain the technical solutions of the present disclosure, rather than to limit the present disclosure. Although the present disclosure is described in detail with reference to the above embodiments, those skilled in the art should understand that they may still modify the technical solutions described in the above embodiments, or make equivalent substitutions of some or all of the technical features recorded therein, without deviating the essence of the corresponding technical solutions from the scope of the technical solutions of the embodiments of the present disclosure.

### INDUSTRIAL APPLICABILITY

In the method of manufacturing a semiconductor structure and the semiconductor structure provided by the embodiments of the present disclosure, a depth-to-width ratio of a gate structure can be effectively improved by setting a supporter, thereby improving the electrical performance of the semiconductor structure. The supporter reliably supports and connects the plurality of gate structures, thereby effectively avoiding peeling of the gate structure during processes such as cleaning, to ensure the product yield.

1. A method of manufacturing a semiconductor structure, comprising:
providing a substrate;
forming a multilayer film stack on the substrate;
forming a supporter at a top of the multilayer film stack; and
etching the multilayer film stack to form a plurality of gate structures arranged at intervals along a first direction, the supporter penetrating a top of each of the plurality of gate structures and extending along the first direction.

2. The method of manufacturing a semiconductor structure according to claim 1, wherein the forming a multilayer film stack on the substrate comprises:
forming a gate dielectric material layer to cover a top surface of the substrate;
forming a gate conductive material layer to cover a top surface of the gate dielectric material layer; and
forming an insulation material cap layer to cover a top surface of the gate conductive material layer, wherein
the gate dielectric material layer, the gate conductive material layer, and the insulation material cap layer jointly constitute the multilayer film stack.

3. The method of manufacturing a semiconductor structure according to claim 2, wherein the forming a gate conductive material layer to cover a top surface of the gate dielectric material layer comprises:
forming a first conductive material layer to cover the top surface of the gate dielectric material layer;
forming a barrier material layer to cover a top surface of the first conductive material layer; and
forming a second conductive material layer to cover the barrier material layer, wherein
the first conductive material layer, the barrier material layer, and the second conductive material layer jointly constitute the gate conductive material layer.

4. The method of manufacturing a semiconductor structure according to claim 2, wherein the forming a supporter at a top of the multilayer film stack comprises:
forming a support material layer on the insulation material cap layer;
forming a first mask layer on the support material layer;
forming a patterned first photoresist layer on the first mask layer, wherein the patterned first photoresist layer comprises a first preset pattern extending along the first direction;
patterning the first mask layer based on the patterned first photoresist layer, to transfer the first preset pattern to the first mask layer; and
etching the support material layer by the patterned first mask layer as a mask, to obtain the supporter.

5. The method of manufacturing a semiconductor structure according to claim 2, wherein the forming a supporter at a top of the multilayer film stack comprises:
forming a second mask layer on the multilayer film stack;
forming a patterned second photoresist layer on the second mask layer, wherein the patterned second photoresist layer comprises a second preset pattern extending along the first direction;
patterning the second mask layer based on the patterned second photoresist layer, to transfer the second preset pattern to the second mask layer;
etching the insulation material cap layer by the patterned second mask layer as a mask to obtain a first trench; and
filling the first trench with a support material layer to form the supporter.

6. The method of manufacturing a semiconductor structure according to claim 4, wherein after the supporter is formed and before the multilayer film stack is etched, the method further comprises:
forming a supplementary material layer on the multilayer film stack, wherein
the supplementary material layer is adjacent to the supporter, and a top surface of the supplementary material layer is flush with a top surface of the supporter; or the supplementary material layer wraps the supporter.

7. The method of manufacturing a semiconductor structure according to claim 5, wherein the etching the multilayer film stack to form a plurality of gate structures arranged at intervals along a first direction, the supporter penetrating a top of each of the plurality of gate structures and extending along the first direction comprises:
forming a third mask layer on the supporter and the multilayer film stack;
forming a patterned third photoresist layer on the third mask layer, wherein the patterned third photoresist layer comprises third preset patterns arranged at intervals along the first direction;
patterning the third mask layer based on the patterned third photoresist layer, to transfer the third preset patterns to the third mask layer; and
etching the multilayer film stack by the patterned third mask layer as a mask, to obtain the plurality of gate structures arranged at intervals along the first direction, and retaining the supporter at the top of each of the gate structures.

8. The method of manufacturing a semiconductor structure according to claim 7, wherein in the step of the etching the multilayer film stack by the patterned third mask layer as a mask,
an etch selectivity between the supporter and the multilayer film stack is less than 1:10.

9. A semiconductor structure, wherein the semiconductor structure comprises:
a substrate;
a plurality of gate structures, located on the substrate and arranged at intervals along a first direction; and
a supporter, penetrating a top of each of the plurality of gate structures and extending along the first direction.

10. The semiconductor structure according to claim 9, wherein the gate structure comprises:
a gate dielectric layer, located on the substrate;
a gate conductive layer, located on the gate dielectric layer; and
an insulation cap layer, located on the gate conductive layer.

11. The semiconductor structure according to claim 10, wherein the gate conductive layer comprises:
a first conductive layer, located on the gate dielectric layer;
a barrier layer, located on the first conductive layer; and
a second conductive layer, located on the barrier layer.

12. The semiconductor structure according to claim 10, wherein the supporter penetrates a top of the insulation cap layer.

13. The semiconductor structure according to claim 10, wherein the gate structure further comprises: a supplementary layer, located on the insulation cap layer;
the supporter penetrates the supplementary layer; and
a top surface of the supplementary layer is flush with a top surface of the supporter.

14. The semiconductor structure according to claim 9, the supporter having a width of 2 nm to 10 nm in a second direction, wherein
the second direction is perpendicular to the first direction and parallel to the substrate.

15. The semiconductor structure according to claim 9, wherein a material of the supporter comprises silicon carbonitride.

16. The semiconductor structure according to claim 9, wherein the plurality of gate structures constitute at least one gate group, each gate group comprises two gate structures that form an annular structure.

17. The semiconductor structure according to claim 16, wherein the supporter penetrates a top of each of 2 to 6 gate groups.

18. The method of manufacturing a semiconductor structure according to claim 6, wherein the etching the multilayer film stack to form a plurality of gate structures arranged at intervals along a first direction, the supporter penetrating a top of each of the plurality of gate structures and extending along the first direction comprises:
forming a third mask layer on the supporter and the multilayer film stack;
forming a patterned third photoresist layer on the third mask layer, wherein the patterned third photoresist layer comprises third preset patterns arranged at intervals along the first direction;
patterning the third mask layer based on the patterned third photoresist layer, to transfer the third preset patterns to the third mask layer; and
etching the multilayer film stack by the patterned third mask layer as a mask, to obtain the plurality of gate structures arranged at intervals along the first direction, and retaining the supporter at the top of each of the gate structures.
